(19) United States
(12) Patent Application Publication
(10) Pub. No.: US 2023/0096713 A1
(43) Pub. Date: Mar. 30, 2023

(54) LIGHT-EMITING ELEMENT

(71) Applicant: SONY SEMICONDUCTOR SOLUTIONS CORPORATION, Kanagawa (JP)

(72) Inventors: Yasunari HANZAWA, Kumamoto (JP); Nobuhiro SUGAWARA, Kumamoto (JP); Masaki SHIOZAKI, Kumamoto (JP); Takeshi SATOU, Kumamoto (JP); Shinsuke NOZAWA, Kumamoto (JP); Hidekazu AOYAGI, Kumamoto (JP)

(73) Assignee: SONY SEMICONDUCTOR SOLUTIONS CORPORATION, Kanagawa (JP)

(21) Appl. No.: 17/798,164

(22) PCT Filed: Feb. 15, 2021
(86) PCT No.: PCT/JP2021/005408

§ 371 Date: Aug. 8, 2022

(30) Foreign Application Priority Data
Feb. 21, 2020 (JP) 2020-028436

(51) Int. Cl. H01L 33/20; H01L 33/10

(52) U.S. Cl. CPC H01L 33/20; H01L 33/10

(57) ABSTRACT

A light-emitting element including: a stacked body; a light-emitting surface; and a reflecting body. The stacked body includes a first semiconductor layer, a second semiconductor layer, and an active layer between the first and second semiconductor layers, and has first and second surfaces on a side opposite to the active layer, and a circumferential surface that connects the first surface and the second surface and includes an end surface of the active layer, a groove formed in the first semiconductor layer from the first surface toward the active layer, having a depth such that the groove is separated from the active layer, and extending in a direction parallel to the first surface. The light-emitting surface is positioned on the first surface on a side opposite to the active layer and emits light generated in the active layer. The reflecting body reflects light emitted from the end surface toward the groove.

### TECHNICAL FIELD

The present technology relates to a light-emitting element having a light-emitting diode structure.

### BACKGROUND ART

A light-emitting element having a light-emitting diode structure has a structure in which an active layer is sandwiched between an n-type semiconductor layer and a p-type semiconductor layer, and emits light by recombination of electrons and holes generated in the active layer. The light generated in the active layer is emitted from a light-emitting surface of the light-emitting element.

In order to improve the light emission efficiency and the light extraction efficiency of the light-emitting element, various element structures have been studied. For example, Patent Literature 1 discloses a light-emitting element in which a reflective layer is provided on a surface excluding the light-emitting surface, of the outer peripheral surface of the light-emitting element, and a recessed and projecting structure is provided on the light-emitting surface as a light extraction structure. In this light-emitting element, the light generated in the active layer is reflected by the reflective layer to the light-emitting surface and is emitted in a predetermined direction by the recessed and projecting structure.

Further, Patent Literature 2 discloses a light-emitting diode in which the thickness of a semiconductor layer is reduced at the outer edge portion of a light-emitting element. In this configuration, by reducing the thickness of the semiconductor layer, the action that makes it difficult for a current to flow in a thin portion of the semiconductor layer, i.e., the current confinement action occurs, and it is possible to collect the light-emitting part of the active layer in the central part of the light-emitting element.

### CITATION LIST

### Patent Literature

Patent Literature 1: Japanese Patent Application Laid-open No. 2015-32809
Patent Literature 2: WO 2016/125344

### DISCLOSURE OF INVENTION

### Technical Problem

However, in recent years, miniaturization of light-emitting elements has been promoted, and there have been problems of a decrease in light emission efficiency and a decrease in light extraction efficiency due to recombination (non-emission recombination) that does not contribute to light emission at the outer edge portion of an active layer.

For example, in the configuration described in Cited Literature 1, a structure for improving the light extraction efficiency is provided, but it is difficult to prevent the light emission efficiency from decreasing due to miniaturization of the light-emitting element. Meanwhile, in the configuration described in Cited Literature 2, it is possible to suppress non-emission recombination in the outer edge portion of an active layer by the current confinement action, but it is difficult to provide a light extraction structure due to miniaturization of the light-emitting element.

In view of the circumstances as described above, it is an object of the present technology to provide a light-emitting element having excellent light emission efficiency and light extraction efficiency.

### Solution to Problem

In order to achieve the above-mentioned object, a light-emitting element according to an embodiment of the present technology includes: a stacked body; a light-emitting surface; and a reflecting body.

The stacked body is a stacked body including a first semiconductor layer having a first semiconductor type, a second semiconductor layer having a second semiconductor type, and an active layer sandwiched between the first semiconductor layer and the second semiconductor layer, and has a first surface that is a surface of the first semiconductor layer on a side opposite to the active layer, a second surface that is a surface of the second semiconductor layer on a side opposite to the active layer, and a circumferential surface that connects the first surface and the second surface to each other and includes an end surface of the active layer, a groove being formed in the first semiconductor layer, the groove being formed from the first surface toward the active layer, having a depth such that the groove is separated from the active layer, and extending in a direction parallel to the first surface.

The light-emitting surface is positioned on the first surface on a side opposite to the active layer and emits light generated in the active layer.

The reflecting body reflects light emitted from the end surface toward the groove.

In accordance with this configuration, it is possible to exert a current confinement action and an optical action by the groove-shaped recessed portion provided in the first semiconductor layer and realize a light-emitting element having excellent light emission efficiency and light extraction efficiency.

The reflecting body may cover the second surface and the circumferential surface and reflect light emitted from the second surface and the circumferential surface toward the light-emitting surface.

The circumferential surface may be inclined such that a distance between the circumferential surfaces increases from the second surface toward the first surface.

The groove may have a V-shaped shape, a U-shaped shape, or a polygonal shape as a cross-sectional shape in a plane perpendicular to a direction in which the groove extends.

A groove wall of the groove may have a vertical surface shape, an inclined surface shape, or a curved surface shape with respect to the light-emitting surface.

The groove wall of the groove may have a smooth surface shape or a recessed and projecting surface shape.

The groove may extend in a direction parallel to or non-parallel to a peripheral edge of the light-emitting surface as viewed from a direction perpendicular to the light-emitting surface.

The groove may include a plurality of grooves provided between the first electrode and the circumferential surface.

The groove may extend linearly or curvedly as viewed from a direction perpendicular to the light-emitting surface.

The groove may be intermittently formed.

The groove may have a constant groove width or a non-constant groove width as viewed from a direction perpendicular to the light-emitting surface.

The groove may be covered with a dielectric film and the dielectric film may form the groove wall of the groove.

The groove may be filled with a dielectric material or no dielectric material.

The light-emitting element may further include: a first electrode that is provided on the first surface and is electrically connected to the first semiconductor layer; and a second electrode that is provided on the second surface and is electrically connected to the second semiconductor layer, in which the groove may be formed between the first electrode and the circumferential surface.

The groove may be formed in a cyclic shape surrounding the first electrode as viewed from a direction perpendicular to the light-emitting surface.

The first electrode may cross the groove.

The first electrode may be electrically connected to the first semiconductor layer inside the groove.

The stacked body may further include a hole-shaped recessed portion that is formed from the first surface toward the active layer in the first semiconductor layer and has a depth such that the hole-shaped recessed portion is separated from the active layer, and

a dielectric film may be formed on an inner surface of the hole-shaped recessed portion.

### BRIEF DESCRIPTION OF DRAWINGS

FIG. 1 is a plan view of a light-emitting element according to an embodiment of the present technology.

FIG. 2 is a cross-sectional view of the light-emitting element.

FIG. 3 is a plan view of a stacked body included in the light-emitting element.

FIG. 4 is a cross-sectional view of the stacked body included in the light-emitting element.

FIG. 5 is an enlarged cross-sectional view of the light-emitting element.

FIG. 6 is a schematic diagram showing the operation of the light-emitting element.

FIG. 7 is a schematic diagram showing the operation of the light-emitting element.

FIG. 8 is a schematic diagram showing the operation of the light-emitting element.

FIG. 9 is a schematic diagram showing the operation of the light-emitting element.

FIG. 10 is a graph showing a relationship between a width of a groove included in the light-emitting element and the light-emitting intensity.

FIG. 11 is a schematic diagram showing the width of the groove included in the light-emitting element.

FIG. 12 is a graph showing a relationship between a position of the groove included in the light-emitting element and the light-emitting intensity.

FIG. 13 is a schematic diagram showing the position of the groove included in the light-emitting element.

FIG. 14 is a plan view showing a plane shape of the groove included in the light-emitting element.

FIG. 15 is a plan view showing the plane shape of the groove included in the light-emitting element.

FIG. 16 is a plan view showing the plane shape of the groove included in the light-emitting element.

FIG. 17 is a plan view showing the plane shape of the groove included in the light-emitting element.

FIG. 18 is a plan view showing the plane shape of the groove included in the light-emitting element.

FIG. 19 is a plan view showing the plane shape of the groove included in the light-emitting element.

FIG. 20 is a plan view showing the plane shape of the groove included in the light-emitting element.

FIG. 21 is a cross-sectional view showing a cross-sectional shape of the groove included in the light-emitting element.

FIG. 22 is a cross-sectional view showing the cross-sectional shape of the groove included in the light-emitting element.

FIG. 23 is a cross-sectional view showing the cross-sectional shape of the groove included in the light-emitting element.

FIG. 24 is a cross-sectional view showing the cross-sectional shape of the groove included in the light-emitting element.

FIG. 25 is a cross-sectional view showing the cross-sectional shape of the groove included in the light-emitting element.

FIG. 26 is a plan view showing the groove and the hole included in the light-emitting element.

FIG. 27 is a cross-sectional view showing the groove and the hole included in the light-emitting element.

FIG. 28 is a plan view showing the groove and the hole included in the light-emitting element.

FIG. 29 is a cross-sectional view showing a circumferential surface shape of the light-emitting element.

FIG. 30 is a cross-sectional view of a light-emitting element according to a modified example of the present technology.

FIG. 31 is a cross-sectional view of the light-emitting element according to the modified example of the present technology.

FIG. 32 is a graph showing a relationship between a thickness of a confinement portion and luminance of a light-emitting element according to an embodiment of the present technology.

FIG. 33 is a graph showing a relationship between a width of a first semiconductor layer and luminance of the light-emitting element according to the embodiment of the present technology.

### MODE(S) FOR CARRYING OUT THE INVENTION

A light-emitting element according to an embodiment of the present technology will be described.

[Structure of Light-Emitting Element]

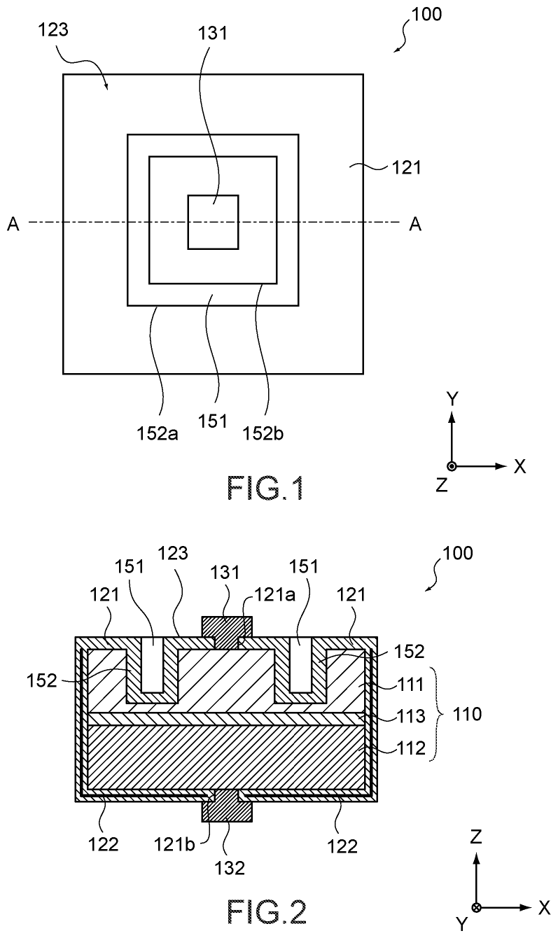

FIG. 1 is a plan view of a light-emitting element 100 according to this embodiment, and FIG. 2 is a cross-sectional view of the light-emitting element 100. FIG. 2 is a cross-sectional view taken along the line A-A in FIG. 1.

As shown in FIG. 1 and in FIG. 2, the light-emitting element 100 includes a stacked body 110, a dielectric film 121, a reflecting body 122, a first electrode 131, and a second electrode 132.

The stacked body 110 is configured by stacking a first semiconductor layer 111, a second semiconductor layer 112, and an active layer 113.

The first semiconductor layer 111 is a layer formed of a p-type semiconductor and can have a structure in which a p-type contact layer and a p-type cladding layer are stacked. The p-type contact layer is formed of, for example, p-GaP and is stacked on the side of the first electrode 131. The p-type cladding layer is formed of, for example, p-AlGaInP and is stacked on the side of the active layer 113. The layer structure and material of the first semiconductor layer 111 are not limited to those shown here, and the first semiconductor layer 111 only needs to be formed of a p-type semiconductor.

The second semiconductor layer 112 is a layer formed of an n-type semiconductor and can have a structure in which an n-type contact layer and an n-type cladding layer are stacked. The n-type contact layer is formed of, for example, GaAs and is stacked on the side of the second electrode 132. The n-type cladding layer is formed of, for example, n-AlGaInP and is formed on the side of the active layer 113. The structure and material of the second semiconductor layer 112 are not limited to those shown here, and the second semiconductor layer 112 only needs to be formed of an n-type semiconductor.

The active layer 113 is a layer sandwiched between the first semiconductor layer 111 and the second semiconductor layer 112 and emits light by recombination of holes flowing from the first semiconductor layer 111 and electrons flowing from the second semiconductor layer 112. The active layer 113 can be, for example, a layer having a multiple quantum well structure in which a large number of quantum well layers formed of GaInP and a large number of barrier layers formed of AlGaInP are alternately stacked. Further, the active layer 113 only needs to be formed of a material that emits light by recombination and may have a single semiconductor layer or a single quantum well structure.

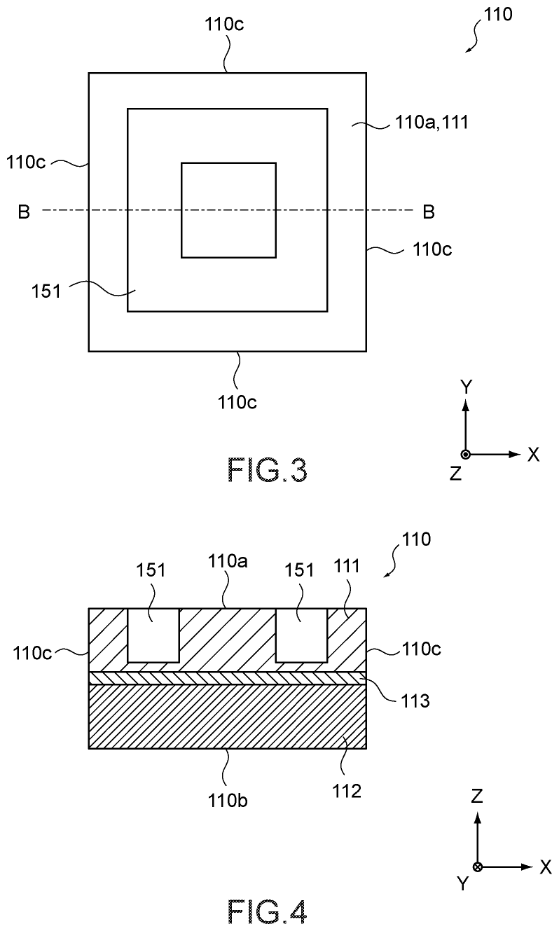

FIG. 3 is a plan view of only the stacked body 110, and FIG. 4 is a cross-sectional view of only the stacked body 110. FIG. 4 is a cross-sectional view taken along the line B-B in FIG. 3. As shown in these figures, a surface of the first semiconductor layer 111 on the side opposite to the active layer 113 is a first surface 110a, and a surface of the second semiconductor layer 112 on the side opposite to the active layer 113 is a second surface 110b. Further, a surface that connects the first surface 110a and the second surface 110b to each other and includes end surfaces of the first semiconductor layer 111, the second semiconductor layer 112, and the active layer 113 is a circumferential surface 110c. Note that in the drawings in the present disclosure, the first surface 110a is a surface parallel to the X direction and the Y direction, i.e., the first surface 110a is a surface parallel to the X-Y plane.

As shown in FIG. 4, a groove 151 is formed from the first surface 110a toward the active layer 113 in the first semiconductor layer 111. The groove 151 is formed to have a depth shallower than the depth reaching the active layer 113, i.e., the groove 151 is formed to have a depth such that the groove 151 is separated from the active layer 113.

Further, as shown in FIG. 3, the groove 151 extends in a direction (X-Y direction) parallel to the first surface 110a. Specifically, the groove 151 can be formed to have a cyclic shape surrounding the first electrode 131 (see FIG. 1) as viewed from a direction (Z direction) perpendicular to the first surface 110a. Note that the shape of the groove 151 is not limited to that shown here, and details thereof will be described below.

The dielectric film 121 is a film formed of a dielectric material such as SiN. The dielectric film 121 is formed on the first surface 110a and the inner surface of the groove 151, and forms a groove wall 152 including the dielectric film 121 in the groove 151 as shown in FIG. 2.

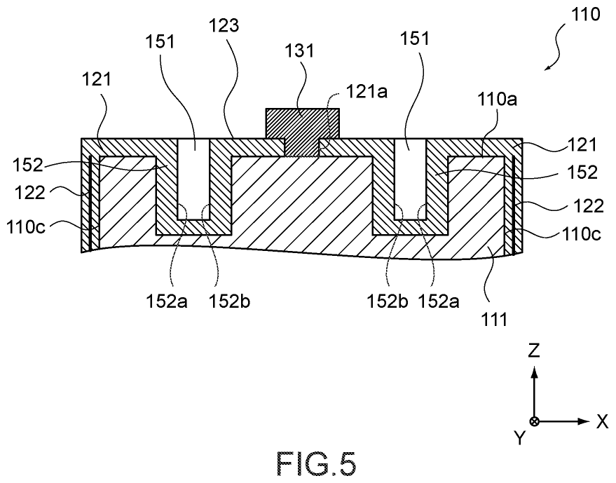

FIG. 5 is an enlarged view of FIG. 2. Hereinafter, as shown in FIG. 5 and FIG. 1, of the groove wall 152, the groove wall on the side of the circumferential surface 110c will be referred to as the outer wall 152a and the groove wall on the side of the first electrode 131 will be referred to as the inner wall 152b. The outer wall 152a and the inner wall 152b may each be a surface perpendicular to the first surface 110a, or may have an inclined surface or the like as described below. The inside of the groove 151 may be a gap or may be filled with a sealing resin or the like (not shown) that covers the periphery of the light-emitting element 100.

Further, the surface of the dielectric film 121 provided on the first surface 110a is a surface from which light generated in the light-emitting element 100 is emitted, and will be referred to as the light-emitting surface 123 below. The light-emitting surface 123 is a surface that is positioned on the first surface 110a on the side opposite to the active layer 113.

Further, the dielectric film 121 is formed also on the second surface 110b and the circumferential surface 110c to cover the periphery of the stacked body 110. As shown in FIG. 2, in the dielectric film 121, an opening 121a is provided on the first surface 110a and an opening 121b is provided on the second surface 110b.

The reflecting body 122 reflects light that enters from the stacked body 110. The reflecting body 122 is suitably provided so as to cover the surface of the stacked body 110 excluding the light-emitting surface 123, i.e., the second surface 110b and the circumferential surface 110c. Further, the reflecting body 122 may be provided only on the end surface of the active layer 113 exposed to the circumferential surface 110c. The reflecting body 122 may be embedded in the dielectric film 121 and may be provided between the surface of the stacked body 110 and the dielectric film 121. The reflecting body 122 can be, for example, a metal film.

The first electrode 131 is provided on the dielectric film 121 formed on the first surface 110a, abuts on the first semiconductor layer 111 via the opening 121a, and is electrically connected to the first semiconductor layer 111. The first electrode 131 is suitably provided at the center of the light-emitting surface 123 as shown in FIG. 1. Further, the first electrode 131 may be formed to cross the groove 151, may abut on the first semiconductor layer 111 inside surrounded by the groove 151, and may be electrically connected to the first semiconductor layer 111. The first electrode 131 can be formed of a conductive material such as a metal.

The second electrode 132 is provided on the dielectric film 121 formed on the second surface 110b, abuts on the second semiconductor layer 112 via the opening 121b, and is electrically connected to the second semiconductor layer 112. The second electrode 131 is suitably provided at the center of the second surface 110b, i.e., at a position opposed to the first electrode 131 via the stacked body 110. The second electrode 132 can be formed of a conductive material such as a metal.

The light-emitting element 100 has the above configuration. As shown in FIG. 1, the light-emitting element 100 can be a square as viewed from a direction (Z direction) perpendicular to the light-emitting surface 123. However, the present technology is not limited thereto, and the light-emitting element 100 may have another shape such as a rectangle, a circle, and a polygon of a triangle or more as viewed from the direction. The size of the light-emitting element 100 is not particularly limited, but, typically, one side of the light-emitting surface 123 is approximately several μm to several ten μm. The light-emitting element 100 can be a micro LED (light emitting diode).

Note that although the first semiconductor layer 111 has been a p-type semiconductor layer and the second semiconductor layer 112 has been an n-type semiconductor layer in the above description, the first semiconductor layer 111 may be an n-type semiconductor layer and the second semiconductor layer 112 may be a p-type semiconductor layer.

[Operation of Light-Emitting Element]

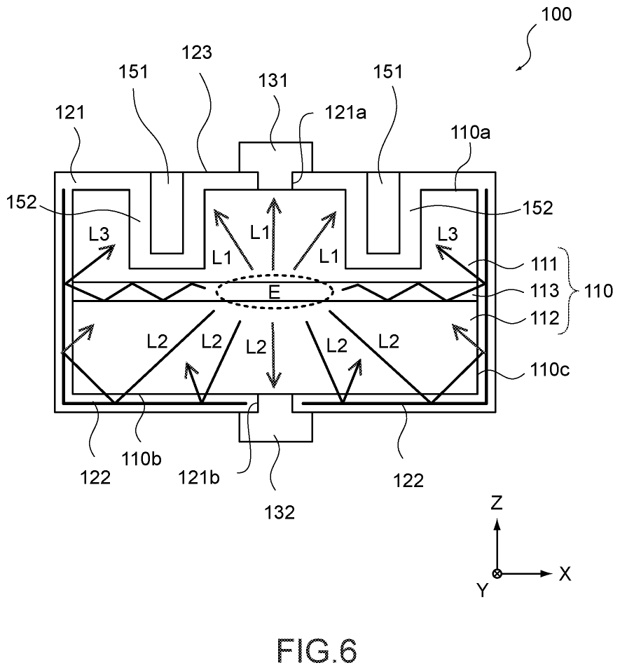

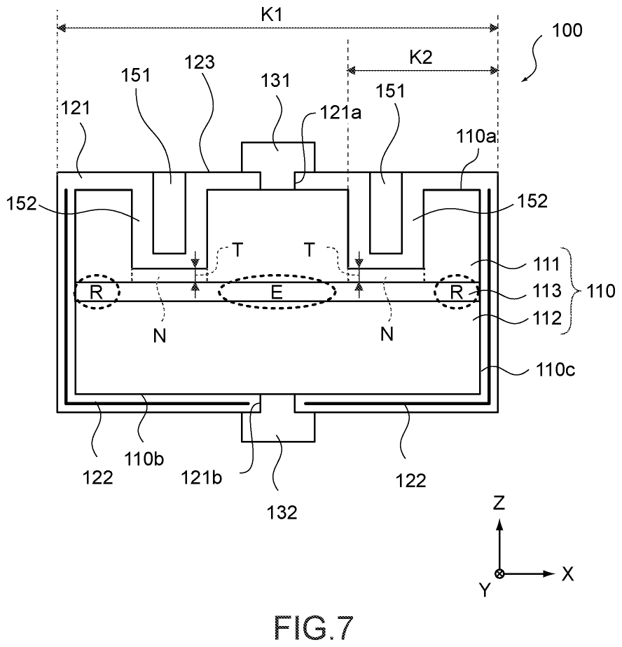

The operation of the light-emitting element 100 will be described. FIG. 6 and FIG. 7 are each a schematic diagram showing the operation of the light-emitting element 100. When a current is applied between the first electrode 131 and the second electrode 132, holes flow from the first semiconductor layer 111 into the active layer 113 and electrons flow from the second semiconductor layer 112 into the active layer 113. In the active layer 113, holes and electrons recombine to emit light.

The light emission in the active layer 113 is centered on the region between the first electrode 131 and the second electrode 132. In FIG. 6, the region in which light emission mainly occurs is shown as the light-emitting region E. Of the light generated in the light-emitting region E, light directed to the light-emitting surface 123 (light L1 in FIG. 6) is emitted from the light-emitting surface 123 as it is. Meanwhile, light directed to the second surface 110b and the circumferential surface 110c (light L2 in FIG. 6) is reflected by the reflecting body 122 and emitted from the light-emitting surface 123 or reflected again by the reflecting body 122.

Further, part of the light generated in the light-emitting region E (light L3 in FIG. 6) propagates in the active layer 113 toward the circumferential surface 110c, is reflected by the reflecting body 122 on the circumferential surface 110c, and is emitted from the light-emitting surface 123.

Here, part of the current flowing between the first electrode 131 and the second electrode 132 causes a recombination without light emission called non-emission recombination in the peripheral edge region of the active layer 113. In FIG. 7, the peripheral edge region of the active layer 113 is shown as the peripheral edge region R. When non-emission recombination occurs in the peripheral edge region R, the current is not used for light emission and the light emission efficiency decreases.

Meanwhile, in the light-emitting element 100, the groove 151 is provided in the first semiconductor layer 111 as described above. By providing the groove 151, the thickness of the first semiconductor layer 111 between the groove 151 and the active layer 113 is reduced as shown in FIG. 7. When this portion where the thickness is reduced is defined as the confinement portion N, the current flowing between the first electrode 131 and the second electrode 132 becomes difficult to pass through the confinement portion N, i.e., is subjected to the current confinement action by the confinement portion N.

As a result, since non-emission recombination in the peripheral edge region R of the active layer 113 is suppressed and a current causes a lot of emission recombination in the light-emitting region A, the light emission efficiency is improved. Therefore, as shown in FIG. 1, causing the groove 151 to have a cyclic shape surrounding the outer periphery of the first electrode 131 is suitable because the periphery of the light-emitting region A can be surrounded by the confinement portion N. Further, even in the case where the groove 151 is not formed into a cyclic shape, it is possible to improve the light emission efficiency because the current confinement action by the confinement portion N can be partially achieved.

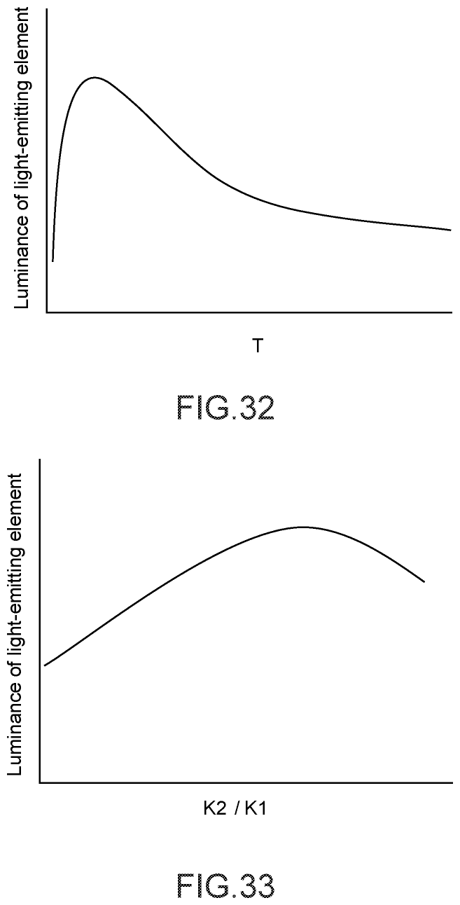

Note that the thickness of the confinement portion N (the thickness T in FIG. 7) only needs to a thickness in which the current confinement action occurs. FIG. 32 is a graph schematically showing a relationship between the thickness T and luminance of the light-emitting element 100. Since the resistance of the confinement portion N increases, a current flowing through the confinement portion N decreases, and a current to the peripheral edge region R decreases as the thickness T is reduced, the luminance improves. The luminance of the light-emitting element 100 increases as the thickness T is reduced, reaches the maximum, and then, sharply decreases as approaching T=0. In the case where T=0, since the active layer 113 is exposed to the groove 151 and non-emission recombination occurs in the vicinity thereof, the luminance decreases.

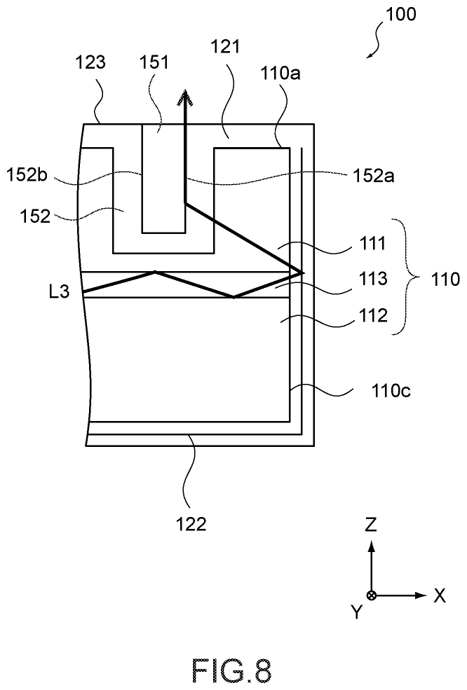

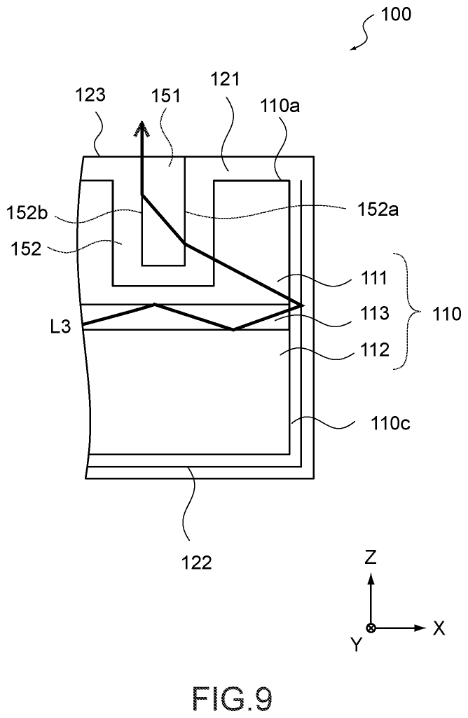

Further, in the light-emitting element 100, also the optical action by the groove 151 occurs. FIG. 8 and FIG. 9 are each a schematic diagram showing the optical action by the groove 151 and an enlarged view of FIG. 6. As described above, the light L3 that has propagated through the active layer 113 is reflected by the reflecting body 122 and enters the groove 151 from the outer peripheral side of the light-emitting element 100.

Here, the inside of the groove 151 includes a gap or a filling such as a sealing resin, and a refractive index difference is generated between the inside of the groove 151 and the dielectric film 121. Therefore, as shown in FIG. 8, the light L3 is refracted on the surface of the dielectric film 121 in the outer wall 152a, and is emitted toward the light-emitting surface 123. Since the light L3 enters the light-emitting surface 123 at a steeper angle as compared with the case where the light L3 is not refracted, the light L3 is projected further forward from the light-emitting surface 123.

Note that although only refraction on the surface of the dielectric film 121 is shown in FIG. 8, refraction at the interface between the first semiconductor layer 111 and the dielectric film 121 may occur. Further, in addition to the light L3, also the light L2 (see FIG. 6) may be refracted by the outer wall 152a similarly.

Further, as shown in FIG. 9, the light L3 that has entered the groove 151 may be refracted on the outer wall 152a, then reflected by the inner wall 152b, and emitted toward the light-emitting surface 123. Also the light L2 may be refracted on the outer wall 152a and then reflected by the inner wall 152b, similarly to the light L3.

[Regarding Adjustment of Light Emission Characteristics]

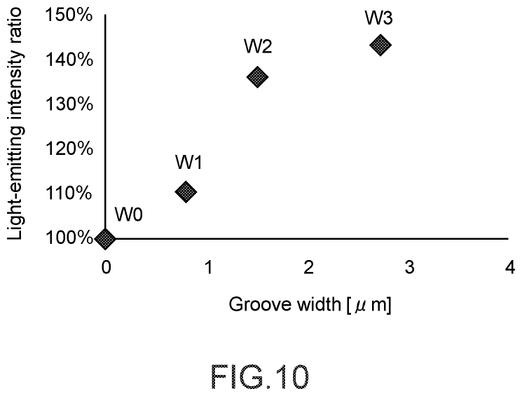

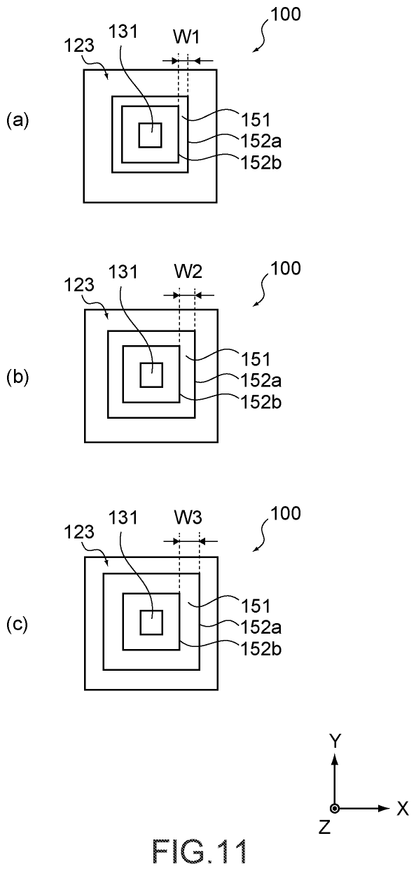

In the light-emitting element 100, the light-emitting intensity can be adjusted by the groove 151. FIG. 10 is a graph showing the ratio of the light-emitting intensity according to the width of the groove 151, and FIG. 11 is a schematic diagram of the light-emitting element 100 that includes the groove 151 having a different width.

The light-emitting intensity shown by “W1” in FIG. 10 is the light-emitting intensity of the light-emitting element 100 that includes the groove 151 having a width W1 in the light-emitting surface 123 as shown in Part (a) of FIG. 11. Similarly, “W2” in FIG. 10 indicates the light-emitting intensity of the light-emitting element 100 that includes the groove wall 152 having a width W2 shown in Part (b) of FIG. 11, and “W3” in FIG. 10 indicates the light-emitting intensity of the light-emitting element 100 that includes the groove wall 152 having a width W3 shown in Part (c) of FIG. 11. As a comparison, “W0” in FIG. 10 indicates the light-emitting intensity of a light-emitting element having the same configuration as that of the light-emitting element 100 except that the groove 151 is not included. Note that the “width” of the groove 151 here means the distance between the outer wall 152a and the inner wall 152b.

As shown in FIG. 10, by providing the groove 151, the light-emitting intensity is improved. Further, the light-emitting intensity differs in accordance with the width of the groove 151, and the light-emitting intensity is improved as the width of the groove 151 increases. This is because the larger the width of the groove 151, the greater the current confinement action by the confinement portion N (see FIG. 7).

FIG. 33 is a graph schematically showing a relationship between the width of the first semiconductor layer 111 and the luminance of the light-emitting element 100. As shown in FIG. 7, the distance between the circumferential surfaces 110c is defined as a distance K1 and the distance between the inner periphery of the groove 151 and the circumferential surface 110c is defined as a K2. As shown in FIG. 32, although the luminance increases as K2/K1 increases from the case where K2/K1=0, the luminance decreases when K2/K1 further increases.

Further, the light-emitting intensity of the light-emitting element 100 can be adjusted not only by the width of the groove wall 152 but also by the position where the groove wall 152 is formed, specifically, the area of the light-emitting surface 123 inside the inner wall 152b.

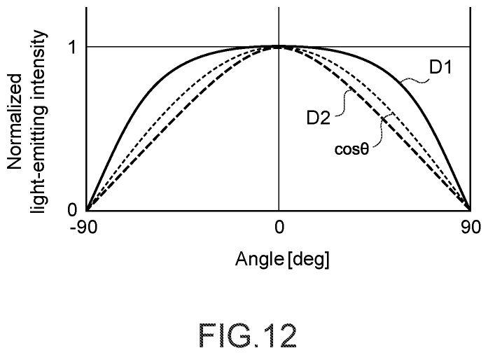

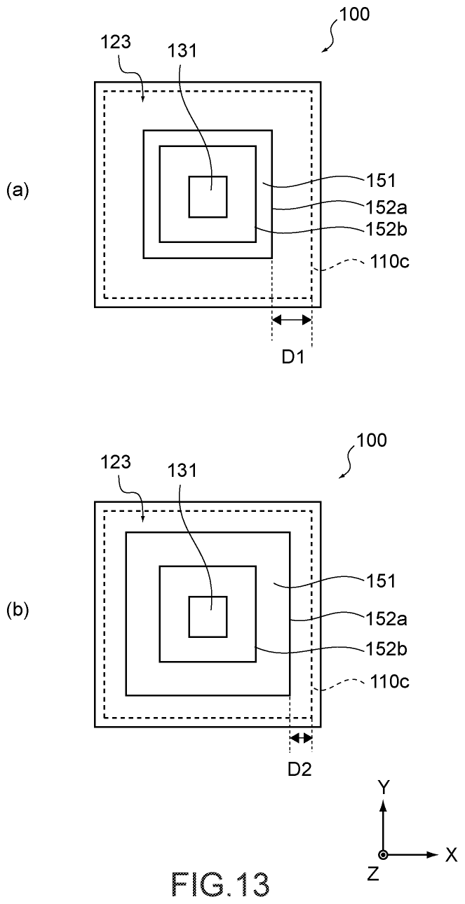

Further, in the light-emitting element 100, the viewing angle characteristics can be adjusted by the groove wall 152. FIG. 12 is a graph showing the light-emitting intensity distribution according to the distance between the outer wall 152a and the circumferential surface 110c, and FIG. 13 is a schematic diagram of the light-emitting element 100 having a different width between the outer wall 152a and the circumferential surface 110c.

In FIG. 12, “D1” indicates the light-emitting intensity distribution of the light-emitting element 100 in which the distance between the outer wall 152a and the circumferential surface 110c is a distance D1 in the light-emitting surface 123 as shown in Part (a) of FIG. 13. Further, in FIG. 12, “D2” indicates the light-emitting intensity distribution of the light-emitting element 100 in which the distance between the outer wall 152a and the circumferential surface 110c is a distance D2 in the light-emitting surface 123 as shown in Part (b) of FIG. 13.

As shown in FIG. 12, in the case where the distance between the outer wall 152a and the circumferential surface 110c is long (distance D1), the light-emitting intensity distribution widened. In the case where the distance between the outer wall 152a and the circumferential surface 110c is short (distance D2), the light-emitting intensity distribution is narrowed. This is due to the angle of incidence (see FIG. 8) or the like of reflected light by the reflecting body 122 on the outer wall 152a.

As described above, in the light-emitting element 100, it is possible to control the light emission characteristics such as the light-emitting intensity and the viewing angle characteristics by the width and formation position of the groove wall 152.

[Effects of Light-Emitting Element]

As described above, in the light-emitting element 100, the light generated by the active layer 113 can be reflected by the reflecting body 122 toward the light-emitting surface 123 and the light travelling to the second surface 110b or the circumferential surface 110c can be used without wasting (see FIG. 6).

Further, by providing the groove 151, the current confinement action can be caused, non-emission recombination in the peripheral edge region of the active layer 113 can be suppressed, and current loss can be reduced (see FIG. 7). Further, the groove wall 152 causes light incident from the outer peripheral side of the light-emitting element 100 by the reflecting body 122 to be emitted toward the light-emitting surface 123 and contributes to the improvement of the light-emitting intensity in the perpendicular direction of the light-emitting surface 123 (see FIG. 8 and FIG. 9).

In general, as the size of the light-emitting element becomes smaller, a decrease in light emission efficiency and a decrease in light extraction efficiency due to non-emission recombination become problem. In the light-emitting element 100, it is possible to improve both the light emission efficiency and the light extraction efficiency as described above and reduce the size of the light-emitting element while suppressing the decrease in light emission efficiency and the decrease in light extraction efficiency.

In addition, it is also possible to control the light-emitting intensity and the light emission characteristics by the width and formation position of the groove 151 and adjust these in accordance with desired characteristics. Further, the shape of the groove 151 can be controlled by the mask pattern or the like in the production process, can be miniaturized, and can be easily made into an arbitrary shape.

[Regarding Shapes of Groove and Groove Inner Wall]

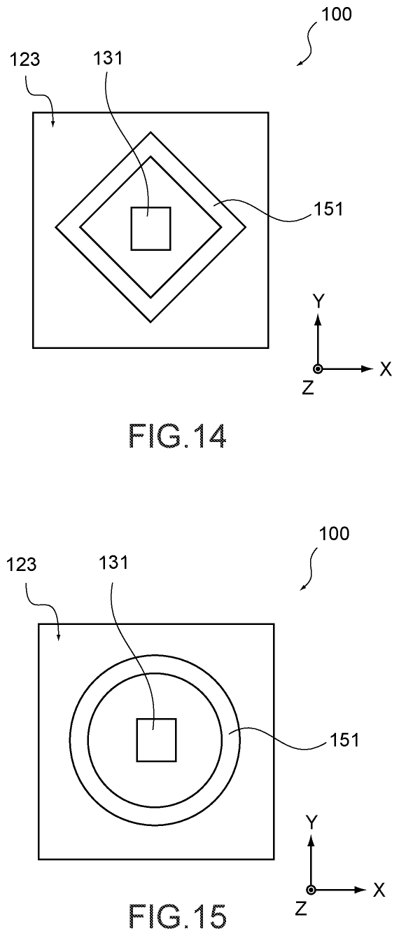

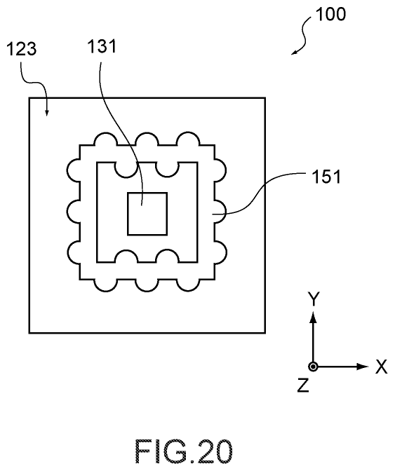

The shape of the groove 151 included in the light-emitting element 100 according to this embodiment is not limited to the above. FIG. 14 to FIG. 25 are schematic diagrams showing various configurations of the groove 151. Note that FIG. 14 to FIG. 20 each show the shape of the groove 151 as viewed from the direction (Z direction) perpendicular to the light-emitting surface 123, and FIG. 20 to FIG. 25 each show the cross-sectional shape of the groove 151 in the plane perpendicular to the extending direction of the groove 151 (plane parallel to the Z direction).

The groove 151 may have a cyclic shape that surrounds the first electrode 131 and extends in parallel with the peripheral edge of a light-emitting surface S as shown in FIG. 1 or may have a cyclic shape that surrounds the first electrode 131 and extends in non-parallel with the peripheral edge of the light-emitting surface 123 as shown in FIG. 14. Further, as shown in FIG. 15, the groove 151 may have an annular shape centered on the first electrode 131.

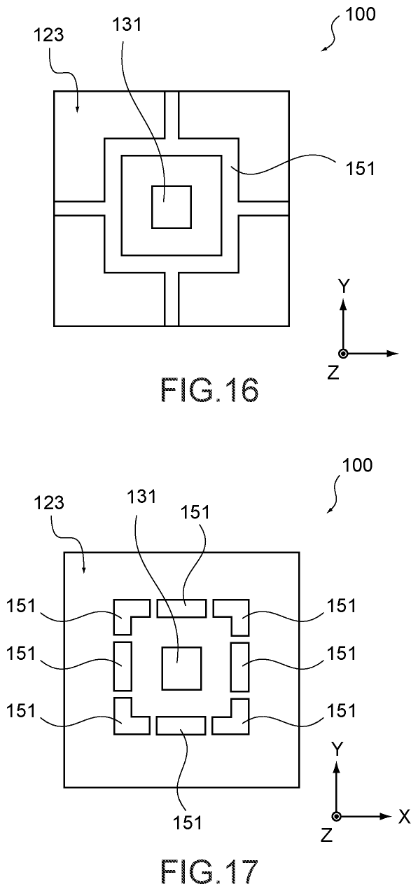

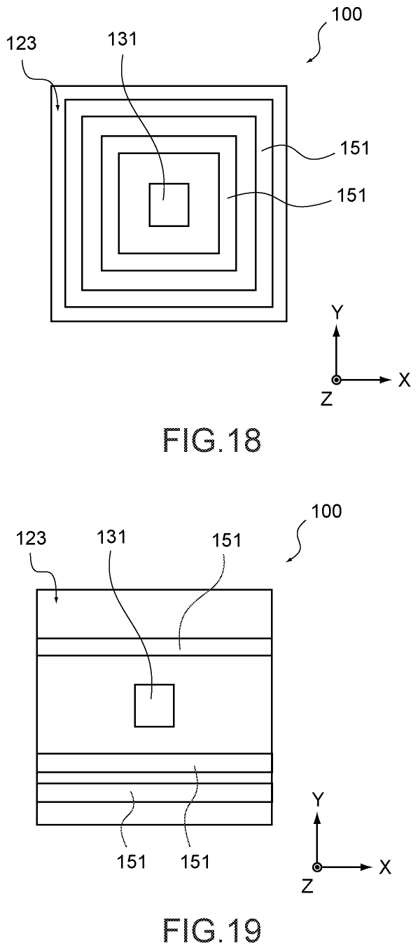

Further, the groove 151 may have a cyclic portion surrounding the first electrode 131 and a branched portion extending toward the peripheral edge of the light-emitting surface 123 as shown in FIG. 16, and may be formed into an intermittent cyclic shape as shown in FIG. 17. Further, a plurality of grooves 151 may be provided between the first electrode 131 and the circumferential surface 110c and may be formed into a double cyclic shape as shown in FIG. 18.

Further, the groove 151 does not necessarily need to be formed into a cyclic shape, may linearly extend to separate the light-emitting surface 123 and the first electrode 131 from each other as shown in FIG. 19, and may be formed linearly and doubly. Further, the groove 151 does not necessarily need to extend linearly and may extend curvedly as shown in FIG. 20. The groove width as viewed from the direction (Z direction) perpendicular to the light-emitting surface 123 of the groove 151 may be constant as shown in FIG. 1 and FIG. 14 to FIG. 19 and does not necessarily need to be constant as shown in FIG. 20.

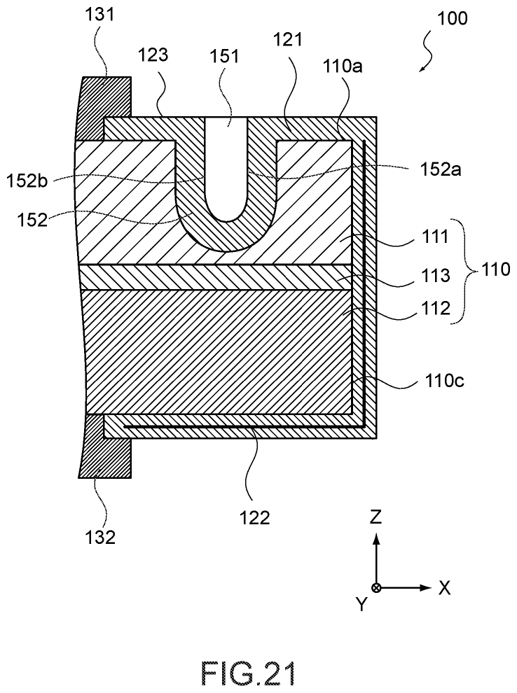

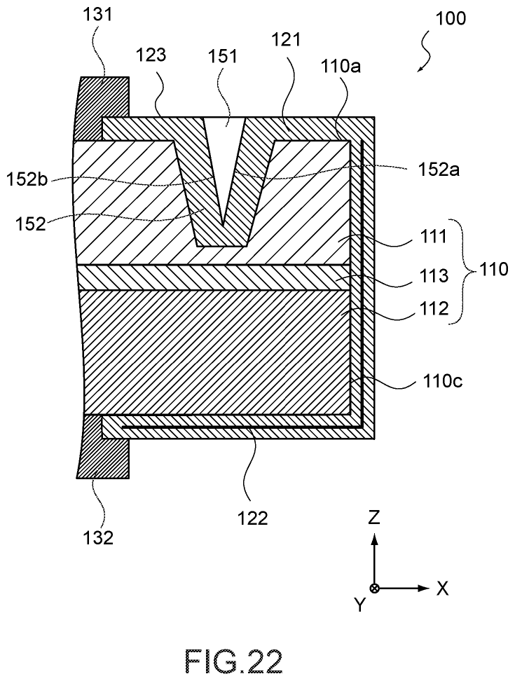

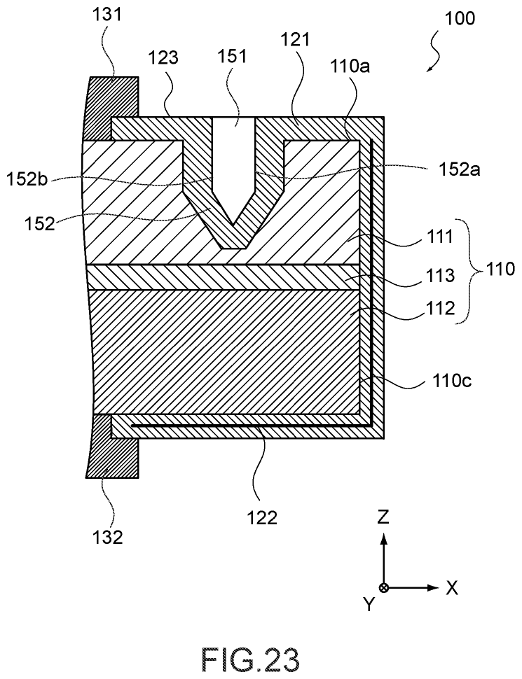

Also the cross-sectional shape of the groove 151 in the plane perpendicular to the extending direction (plane parallel to the Z direction) is not limited the rectangular shape shown in FIG. 2. The groove 151 may include the groove wall 152 having a U-shaped shape as shown in FIG. 21, a V-shaped shape as shown in FIG. 22, or a polygonal shape as shown in FIG. 23.

Further, in the groove wall 152, the outer wall 152a and the inner wall 152b may have a vertical surface shape with respect to the light-emitting surface 123 as shown in FIG. 5, and part of the outer wall 152a and the inner wall 152b may have an inclined surface shape inclined with respect to the plane perpendicular to the light-emitting surface 123 as shown in FIG. 23. Further, only one of the outer wall 152a and the inner wall 152b may have an inclined surface shape.

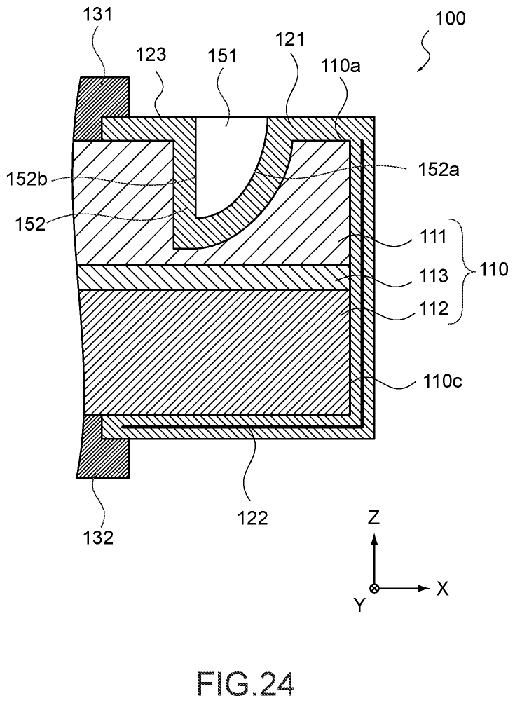

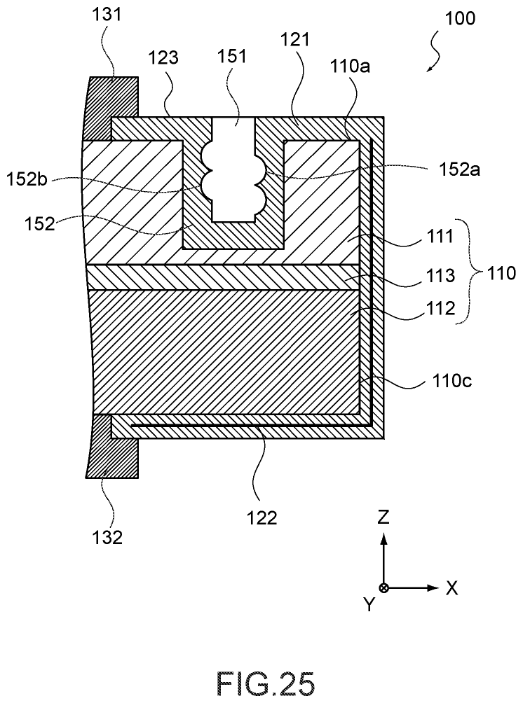

Further, in the groove wall 152, the outer wall 152a may be formed in a curved surface shape as shown in FIG. 24, the inner wall 152b may have a curved surface shape, or both the outer wall 152a and the inner wall 152b may have a curved surface shape. Also the wall surfaces of the outer wall 152a and the inner wall 152b may have a smooth surface as shown in FIG. 1 or may have a recessed and projecting surface shape in which a recessed and projecting portion has been formed as shown in FIG. 25.

As described above, the groove 151 and the groove wall 152 can have various shapes and can have an appropriate shape in accordance with the size and shape of the light-emitting element 100, desired light emission characteristics, and the like, in addition to the various shapes described above.

[Regarding Hole]

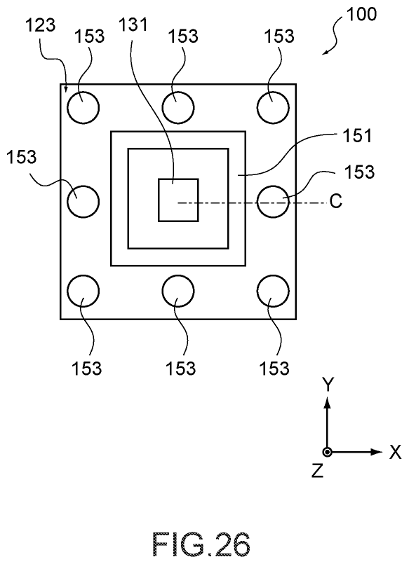

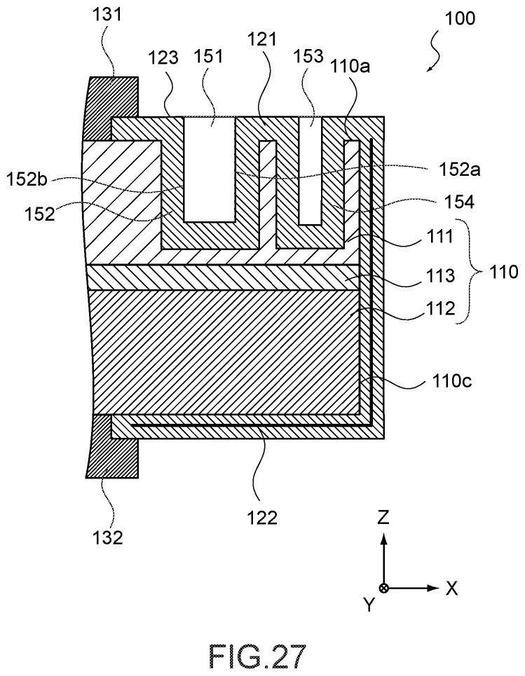

The light-emitting element 100 includes the groove 151 formed in the light-emitting surface 123 as described above but can include a hole formed in the light-emitting surface 123, in addition to the groove 151. FIG. 26 is a plan view of the light-emitting element 100 including holes 153, and FIG. 27 is a cross-sectional view taken along the line C in FIG. 26.

As shown in FIG. 26 and FIG. 27, the holes 153 each include a hole-shaped recessed portion 154 that is formed from the first surface 110a toward the active layer 113 in the first semiconductor layer 111 and has a depth such that the hole-shaped recessed portion 154 is separated from the active layer 113, and the dielectric film 121 provided in the hole-shaped recessed portion 154. The hole 153 may have a depth equivalent to that of the groove 151 or may have a depth shallower than that of the groove 151.

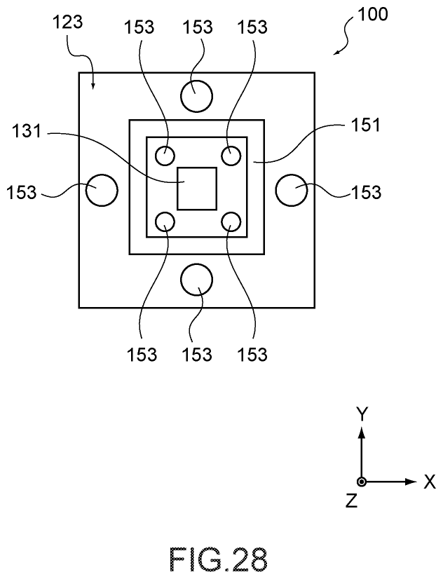

Also the holes 153 are capable of imparting the optical action to reflected light by the reflecting body 122 and adjusting the light emission characteristics of the light-emitting element 100 by increasing the light path. As shown in FIG. 26, the hole 153 can be provided between the groove 151 and the peripheral edge of the light-emitting element 100. Further, FIG. 28 is a plan view showing another arrangement of the holes 153, and the holes 153 may be provided between the groove 151 and the first electrode 131 as shown in the figure.

The shape of the hole 153 on the light-emitting surface 123 may be a circular shape as shown in FIG. 26 and FIG. 28 or may be another shape. Also the size and number of the holes 153 are not limited to those shown here.

[Regarding Circumferential Surface]

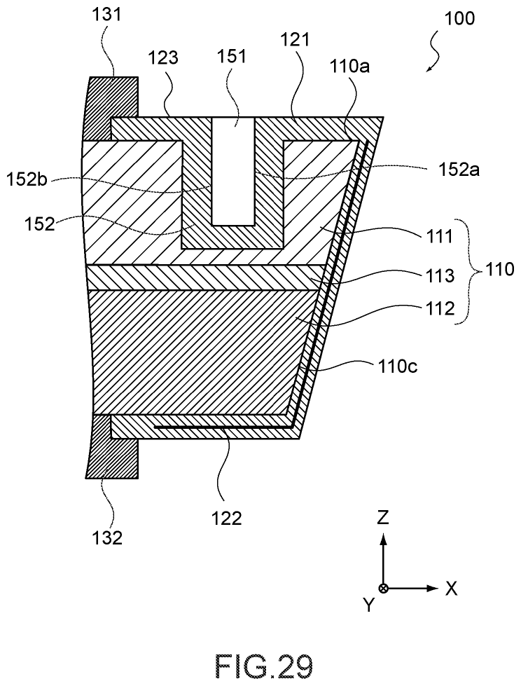

As described above, the light-emitting element 100 has the circumferential surface 110 that connects the first surface 110a and the second surface 110b to each other, and the circumferential surface 110c may be an inclined surface. FIG. 29 is a cross-sectional view of the light-emitting element 100 having the inclined circumferential surface 110c.

As shown in the figure, the circumferential surface 110c can be inclined with respect to the plane perpendicular to the light-emitting surface 123 such that the distance between the circumferential surfaces 110c increases from the second surface 110b toward the first surface 110a.

By making the circumferential surface 110c inclined in this way, light that enters the circumferential surface 110c is easily reflected by the reflecting body 122 toward the light-emitting surface 123 and the amount of light projected forward from the light-emitting surface 123 can be increased. Note that the entire circumferential surface 110c may inclined as shown in FIG. 29 or only part of the circumferential surface 110c may be inclined. Further, the circumferential surface 110c may have a curved surface formed such that the distance between the circumferential surfaces 110c increases from the second surface 110b toward the first surface 110a or may have a polygonal shape.

### Modified Example

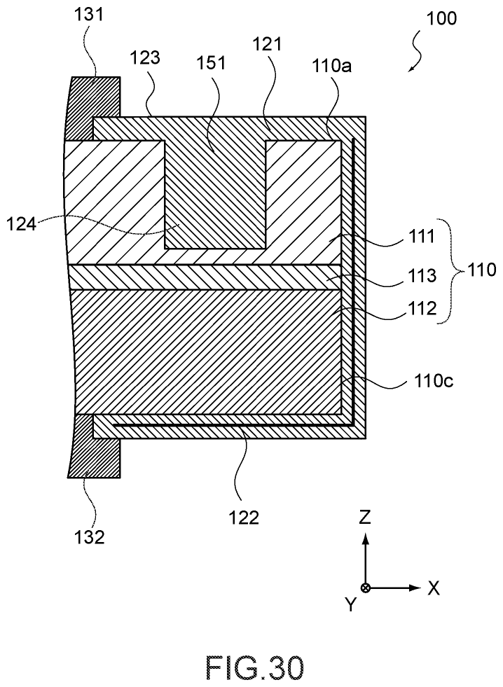

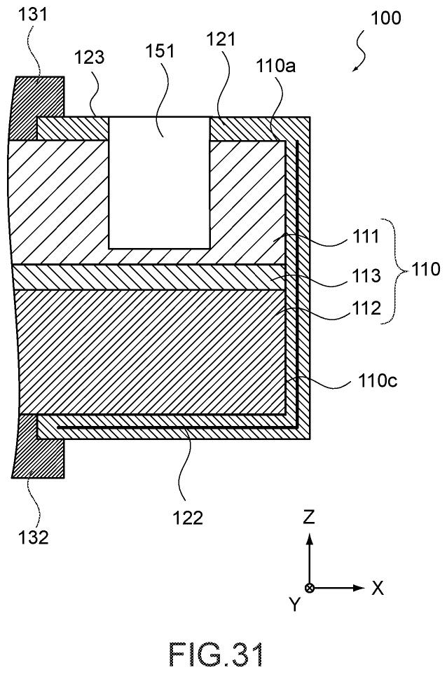

A modified example of the light-emitting element 100 according to this embodiment will be described. FIG. 30 and FIG. 31 are each a cross-sectional view of the light-emitting element 100 according to a modified example.

Although the light-emitting element 100 includes the groove wall 152 including the dielectric film 121 as described above, the groove 151 may be filled with a dielectric material 124 as shown in FIG. 30. Even with this configuration, it is possible to cause the current confinement action by the groove 151 and cause the optical action such as refraction on the interface between the groove 151 and the dielectric material 124.

Further, as shown in FIG. 31, the groove 151 does not necessarily need to be filled with the dielectric material 124. Also in this case, similarly, it is possible to cause the current confinement action by the groove 151 and cause the optical action such as refraction on the surface of the groove 151.

It should be noted that the present technology may also take the following configurations.

(1) A light-emitting element, including:

a stacked body that is a stacked body including a first semiconductor layer having a first semiconductor type, a second semiconductor layer having a second semiconductor type, and an active layer sandwiched between the first semiconductor layer and the second semiconductor layer, and has a first surface that is a surface of the first semiconductor layer on a side opposite to the active layer, a second surface that is a surface of the second semiconductor layer on a side opposite to the active layer, and a circumferential surface that connects the first surface and the second surface to each other and includes an end surface of the active layer, a groove being formed in the first semiconductor layer, the groove being formed from the first surface toward the active layer, having a depth such that the groove is separated from the active layer, and extending in a direction parallel to the first surface;

a light-emitting surface that is positioned on the first surface on a side opposite to the active layer and emits light generated in the active layer; and

a reflecting body that reflects light emitted from the end surface toward the groove.

(2) The light-emitting element according to (1) above, in which

the reflecting body covers the second surface and the circumferential surface and reflects light emitted from the second surface and the circumferential surface toward the light-emitting surface.

(3) The light-emitting element according to (1) or (2) above, in which

the circumferential surface is inclined such that a distance between the circumferential surfaces increases from the second surface toward the first surface.

(4) The light-emitting element according to any one of (1) to (3) above, in which

the groove has a V-shaped shape, a U-shaped shape, or a polygonal shape as a cross-sectional shape in a plane perpendicular to a direction in which the groove extends.

(5) The light-emitting element according to any one of (1) to (3) above, in which

a groove wall of the groove has a vertical surface shape, an inclined surface shape, or a curved surface shape with respect to the light-emitting surface.

(6) The light-emitting element according to any one of (1) to (3) above, in which

the groove wall of the groove has a smooth surface shape or a recessed and projecting surface shape.

(7) The light-emitting element according to any one of (1) to (6) above, in which

the groove extends in a direction parallel to or non-parallel to a peripheral edge of the light-emitting surface as viewed from a direction perpendicular to the light-emitting surface.

(8) The light-emitting element according to any one of (1) to (7) above, in which

the groove includes a plurality of grooves provided between the first electrode and the circumferential surface.

(9) The light-emitting element according to any one of (1) to (8) above, in which

the groove extends linearly or curvedly as viewed from a direction perpendicular to the light-emitting surface.

(10) The light-emitting element according to any one of (1) to (9) above, in which

the groove is intermittently formed.

(11) The light-emitting element according to any one of (1) to (10) above, in which

the groove has a constant groove width or a non-constant groove width as viewed from a direction perpendicular to the light-emitting surface.

(12) The light-emitting element according to any one of (1) to (11) above, in which

the groove is covered with a dielectric film and the dielectric film forms the groove wall of the groove.

(13) The light-emitting element according to any one of (1) to (11) above, in which

the groove is filled with a dielectric material or no dielectric material.

(14) The light-emitting element according to any (1) to (13) above, further including

a first electrode that is provided on the first surface and is electrically connected to the first semiconductor layer; and

a second electrode that is provided on the second surface and is electrically connected to the second semiconductor layer, in which

the groove is formed between the first electrode and the circumferential surface.

(15) The light-emitting element according to (14) above, in which

the groove is formed in a cyclic shape surrounding the first electrode as viewed from a direction perpendicular to the light-emitting surface.

(16) The light-emitting element according to (14) above, in which

the first electrode crosses the groove.

(17) The light-emitting element according to (16) above, in which

the first electrode is electrically connected to the first semiconductor layer inside the groove.

(18) The light-emitting element according to any one of (1) to (17) above, in which

the stacked body further includes a hole-shaped recessed portion that is formed from the first surface toward the active layer in the first semiconductor layer and has a depth such that the hole-shaped recessed portion is separated from the active layer, and

a dielectric film is formed on an inner surface of the hole-shaped recessed portion.

### REFERENCE SIGNS LIST

100 light-emitting element
110 stacked body
111 first semiconductor layer
112 second semiconductor layer
113 active layer
121 dielectric film
122 reflecting body
123 light-emitting surface
131 first electrode
132 second electrode
151 groove
152 groove wall
152a outer wall
152b inner wall
153 hole

What is claimed is:

1. A light-emitting element, comprising:
a stacked body that is a stacked body including a first semiconductor layer having a first semiconductor type, a second semiconductor layer having a second semiconductor type, and an active layer sandwiched between the first semiconductor layer and the second semiconductor layer, and has a first surface that is a surface of the first semiconductor layer on a side opposite to the active layer, a second surface that is a surface of the second semiconductor layer on a side opposite to the active layer, and a circumferential surface that connects the first surface and the second surface to each other and includes an end surface of the active layer, a groove being formed in the first semiconductor layer, the groove being formed from the first surface toward the active layer, having a depth such that the groove is separated from the active layer, and extending in a direction parallel to the first surface;
a light-emitting surface that is positioned on the first surface on a side opposite to the active layer and emits light generated in the active layer; and
a reflecting body that reflects light emitted from the end surface toward the groove.

2. The light-emitting element according to claim 1, wherein
the reflecting body covers the second surface and the circumferential surface and reflects light emitted from the second surface and the circumferential surface toward the light-emitting surface.

3. The light-emitting element according to claim 2, wherein
the circumferential surface is inclined such that a distance between the circumferential surfaces increases from the second surface toward the first surface.

4. The light-emitting element according to claim 1, wherein
the groove has a V-shaped shape, a U-shaped shape, or a polygonal shape as a cross-sectional shape in a plane perpendicular to a direction in which the groove extends.

5. The light-emitting element according to claim 1, wherein
a groove wall of the groove has a vertical surface shape, an inclined surface shape, or a curved surface shape with respect to the light-emitting surface.

6. The light-emitting element according to claim 1, wherein
the groove wall of the groove has a smooth surface shape or a recessed and projecting surface shape.

7. The light-emitting element according to claim 1, wherein
the groove extends in a direction parallel to or non-parallel to a peripheral edge of the light-emitting surface as viewed from a direction perpendicular to the light-emitting surface.

8. The light-emitting element according to claim 1, wherein
the groove includes a plurality of grooves provided between the first electrode and the circumferential surface.

9. The light-emitting element according to claim 1, wherein
the groove extends linearly or curvedly as viewed from a direction perpendicular to the light-emitting surface.

10. The light-emitting element according to claim 1, wherein
the groove is intermittently formed.

11. The light-emitting element according to claim 1, wherein
the groove has a constant groove width or a non-constant groove width as viewed from a direction perpendicular to the light-emitting surface.

12. The light-emitting element according to claim 1, wherein
the groove is covered with a dielectric film and the dielectric film forms the groove wall of the groove.

13. The light-emitting element according to claim 1, wherein
the groove is filled with a dielectric material or no dielectric material.

14. The light-emitting element according to claim 1, further comprising
a first electrode that is provided on the first surface and is electrically connected to the first semiconductor layer; and
a second electrode that is provided on the second surface and is electrically connected to the second semiconductor layer, wherein
the groove is formed between the first electrode and the circumferential surface.

15. The light-emitting element according to claim 14, wherein
the groove is formed in a cyclic shape surrounding the first electrode as viewed from a direction perpendicular to the light-emitting surface.

16. The light-emitting element according to claim 14, wherein
the first electrode crosses the groove.

17. The light-emitting element according to claim 16, wherein
the first electrode is electrically connected to the first semiconductor layer inside the groove.

18. The light-emitting element according to claim 1, wherein
the stacked body further includes a hole-shaped recessed portion that is formed from the first surface toward the active layer in the first semiconductor layer and has a depth such that the hole-shaped recessed portion is separated from the active layer, and
a dielectric film is formed on an inner surface of the hole-shaped recessed portion.
